(19) United States
(12) Patent Application Publication
(10) Pub. No.: US 2025/0151387 A1
(43) Pub. Date: May 8, 2025

(54) ENABLING MULTI-VT IN CFETS WITH COMMON GATES AND A COMMON DIPOLE DOPANT

(71) Applicant: Taiwan Semiconductor Manufacturing Co., Ltd., Hsinchu (TW)

(72) Inventors: Cheng-Ming Lin, Kaohsiung City (TW); Tsung-Kai Chiu, Zhubei City (TW); Wei-Yen Woon, Taoyuan City (TW); Szuya Liao, Zhubei (TW)

(21) Appl. No.: 18/504,874

(22) Filed: Nov. 8, 2023

(51) Int. Cl. H01L 27/092; H01L 21/822; H01L 21/8238; H01L 29/06; H01L 29/423; H01L 29/51; H01L 29/66; H01L 29/775

(52) U.S. Cl. CPC H10D 84/856; H10D 30/014; H10D 30/43; H10D 30/6735; H10D 62/121; H10D 64/017; H10D 64/689; H10D 84/0167; H10D 84/017; H10D 84/0181; H10D 84/0186; H10D 84/038; H10D 88/01

(57) ABSTRACT

A method includes forming a first semiconductor channel region and a second semiconductor channel region, wherein the second semiconductor channel region overlaps the first semiconductor channel region, forming a first gate dielectric on the first semiconductor channel region, and forming a second gate dielectric on the second semiconductor channel region. A first dipole film and a second dipole film are formed on the first gate dielectric and the second gate dielectric, respectively. The Dipole dopants in the first dipole film and the second dipole film are driven into the first gate dielectric and the second gate dielectric, respectively. The first dipole film and the second dipole film are then removed. A gate electrode is formed on both of the first gate dielectric and the second gate dielectric to form first transistor and a second transistor, respectively.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 24A and 24B are views of intermediate stages in the manufacturing of CFETs in accordance with some embodiments.

FIG. 25 illustrates the relationship between effective work functions, the threshold voltages, and dipole film thicknesses of PFETs and NFETs in accordance with some embodiments.

FIGS. 26-1, 26-2, and 26-3 illustrate the schematic dipole dopant atomic percentages in the gate dielectrics of a plurality of FETs in accordance with some embodiments.

FIG. 27 illustrates a flow chart for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. Throughout the description, the terms “FET” and “transistor” are used interchangeably. In accordance with some embodiments, A CFET structure includes a plurality of NFETs and PFETs, which are formed as having multiple threshold voltages. A plurality of common p-type metal gates are shared, each by a pair of FETs (including an NFET and a PFET) in a same CFET structure. An n-type dipole dopant is used. The threshold voltages of the PFETs and NFETs are adjusted by doping the gate dielectrics of the NFETs and PFETs to different atomic percentages. Although the p-type metal is also used for the NFETs, the effective work function values of the work function layers of the NFETs are brought down to the range of n-type work functions through heavily doping the gate dielectrics of the NFETs with the dipole dopant.

It is appreciated that although p-type metal gates and n-type dipole dopants are used as an example, n-type metal gates and p-type dipole dopants may also be used to form a plurality of CFETS having different threshold voltages. Also, while Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like.

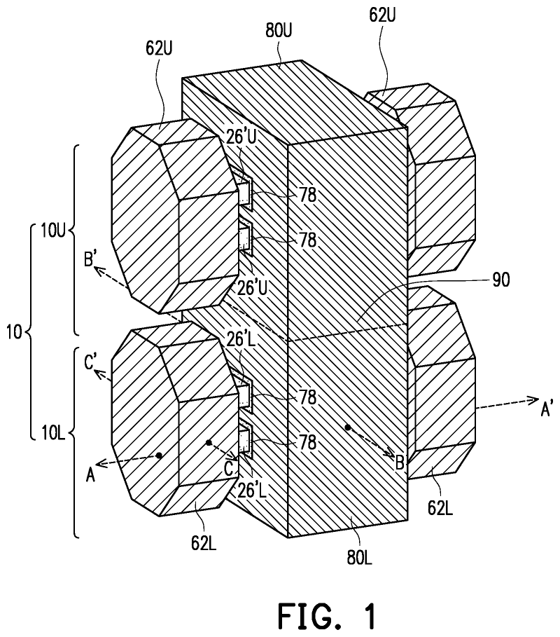

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Cross-section C-C′ is a vertical cross-section that is parallel to cross-section B-B′ and extends through the source/drain regions 62 of the CFETs. Subsequent figures may refer to these reference cross-sections for clarity.

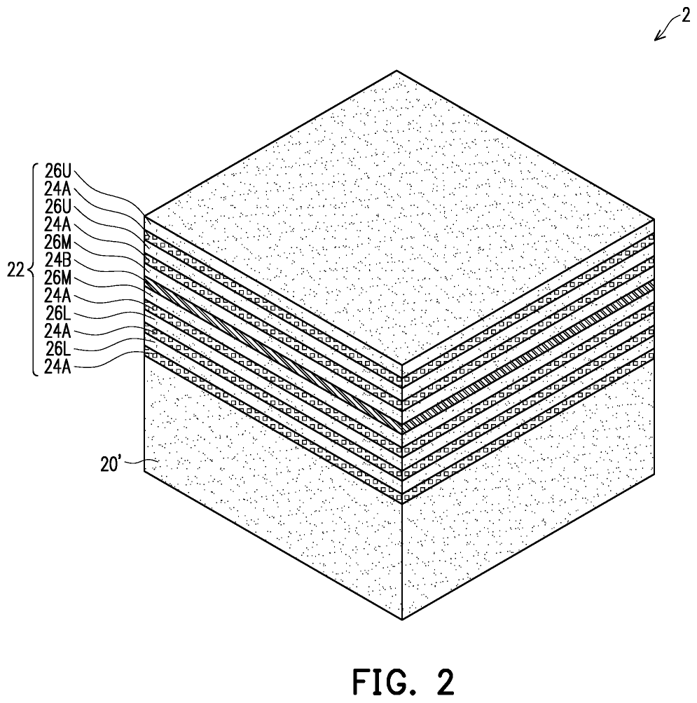

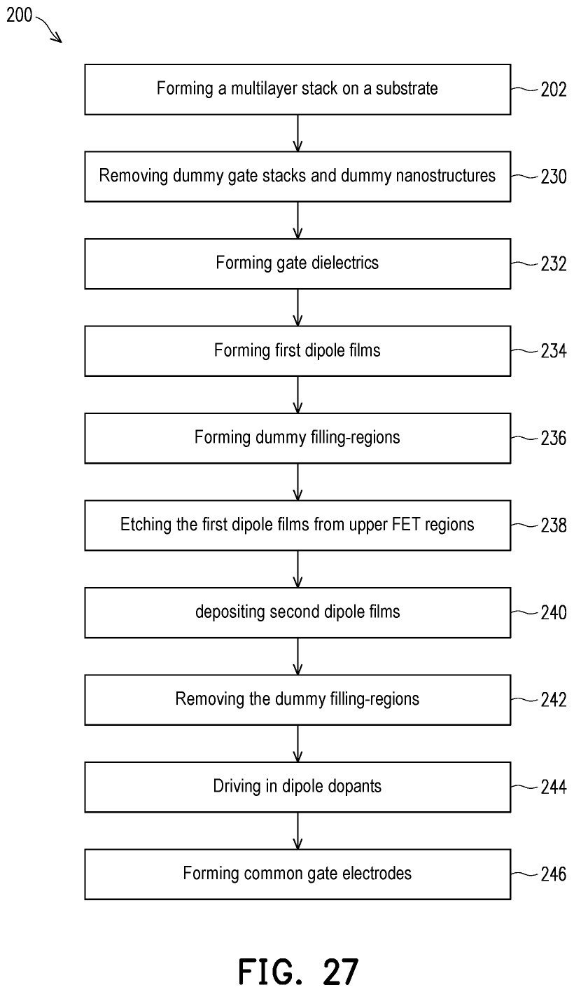

FIGS. 2 through 24A and 24B illustrate the cross-sectional views of intermediate stages in the formation of CFETs (as schematically represented in FIG. 1) in accordance with some embodiments. The corresponding processes are also reflected schematically in the process flow shown in FIG. 27. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′in FIG. 1. The figures having digits followed by letter “C” illustrate the vertical cross-sectional views along a similar cross-section as the vertical reference cross-section C-C′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The respective process is illustrated as process 202 in the process flow 200 as shown in FIG. 27. The multi-layer stack 22 includes alternating dummy semiconductor layers 24 (including dummy semiconductor layers 24A and a dummy semiconductor layer 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

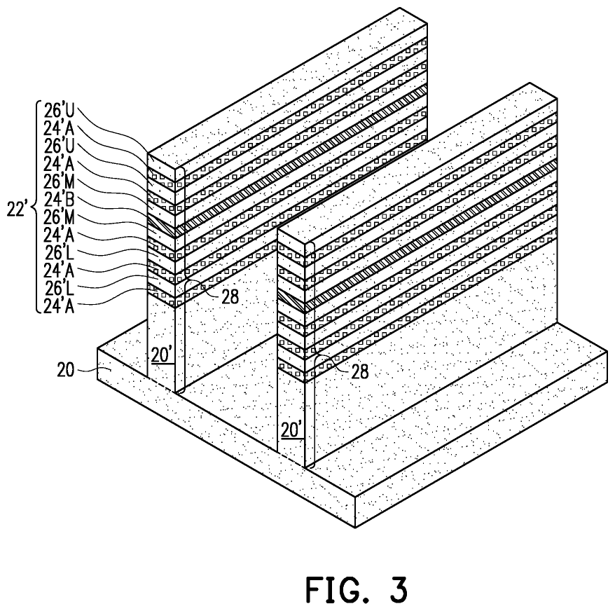

In FIG. 3, multi-layer stack 22 and substrate 20 are patterned to form semiconductor strips 28. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

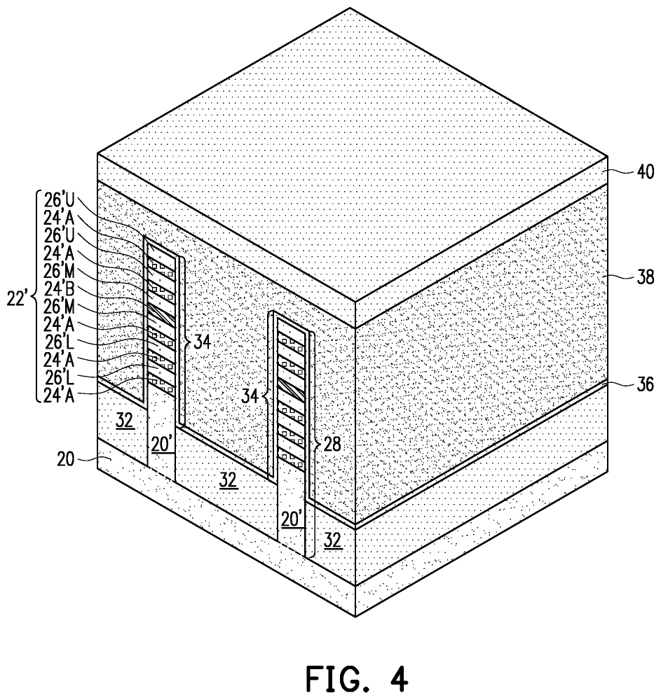

In FIG. 4, isolation regions 32 are formed over the substrate 20 and between adjacent semiconductor strips 28. Isolation regions 32 may include a dielectric liner and a dielectric material over the dielectric liner.

Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

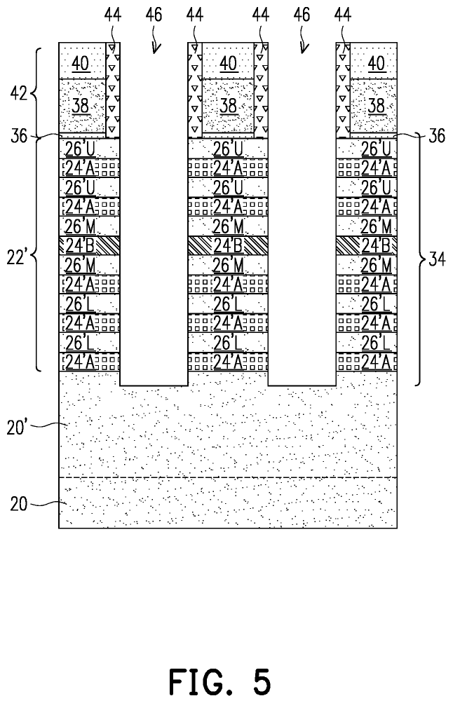

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 are also formed.

Source/drain recesses 46 are then formed in semiconductor strips 28. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

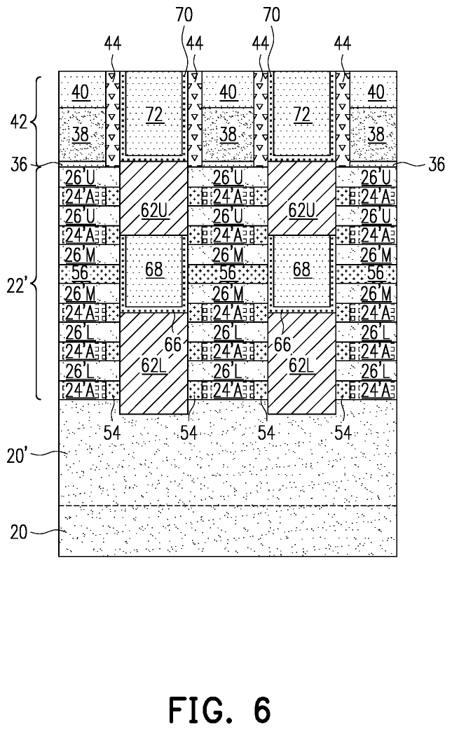

Dummy nanostructures 24′A are laterally recessed, and a dielectric material is filled into the respective recesses to form inner spacers 54, which are dielectric spacers. The resulting structure is shown in FIG. 6.

Next, lower epitaxial source/drain regions 62L are formed in the lower portions of the source/drain recesses 46 (FIG. 5). The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants

A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

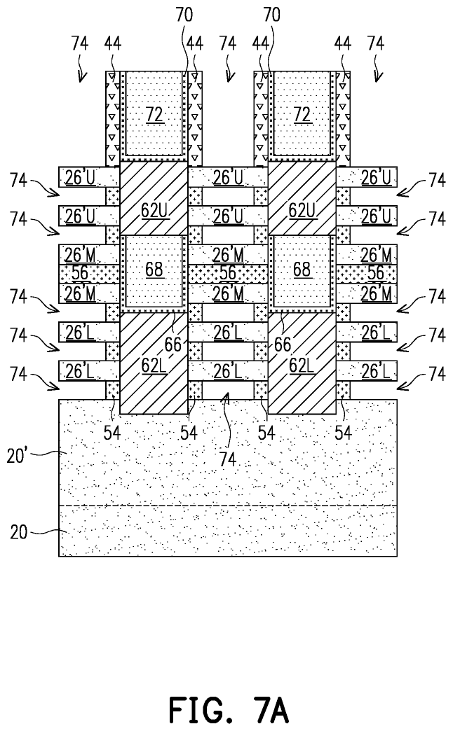

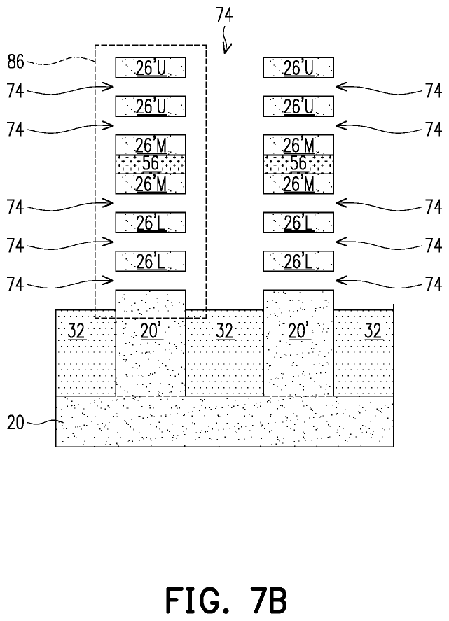

The dummy gate stacks 42 are then removed in one or more etching processes, so that recesses 74 are formed, as shown in FIGS. 7A and 7B. The respective process is illustrated as process 230 in the process flow 200 as shown in FIG. 41. Each of recesses 74 exposes and/or overlies portions of multi-layer stacks 22′.

The remaining portions of the dummy nanostructures 24′A (FIG. 6) are then removed through etching, so that recesses 74 extend between the semiconductor nanostructures 26′. In the etching process, the dummy nanostructures 24′A is etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

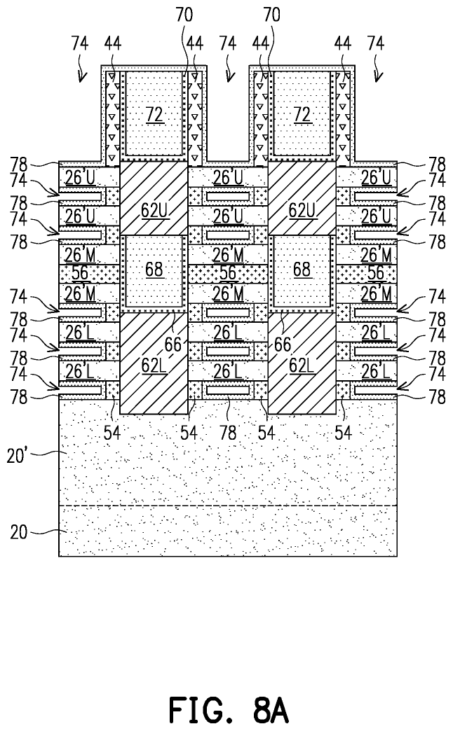

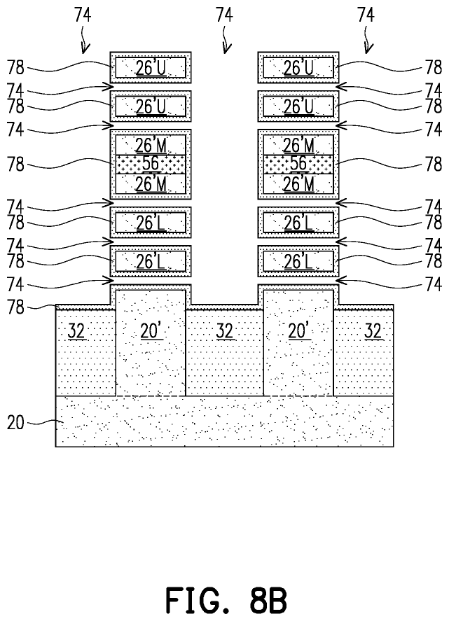

In FIGS. 8A and 8B, gate dielectrics 78 are formed in recesses 74, and are formed on the exposed semiconductor nanostructures 26′. The respective process is illustrated as process 232 in the process flow 200 as shown in FIG. 41. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

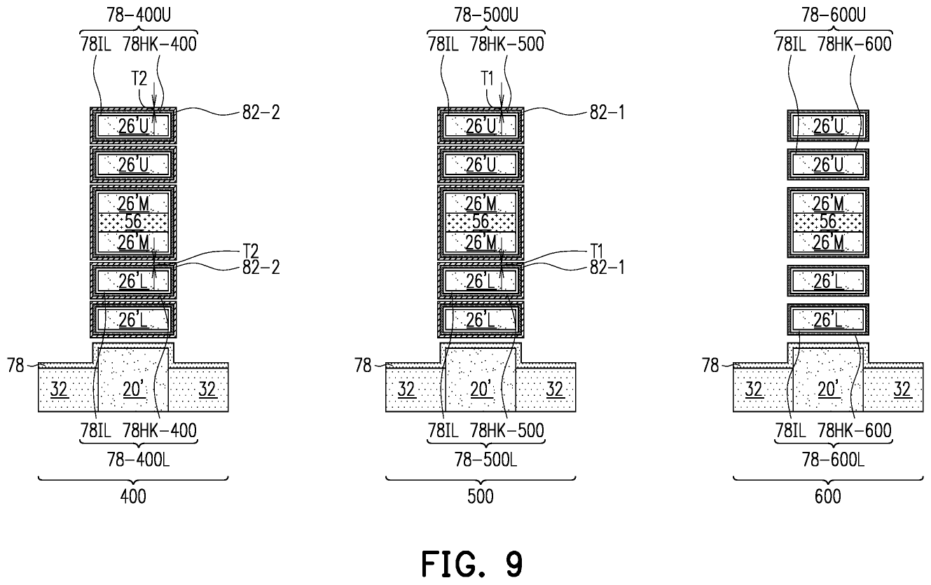

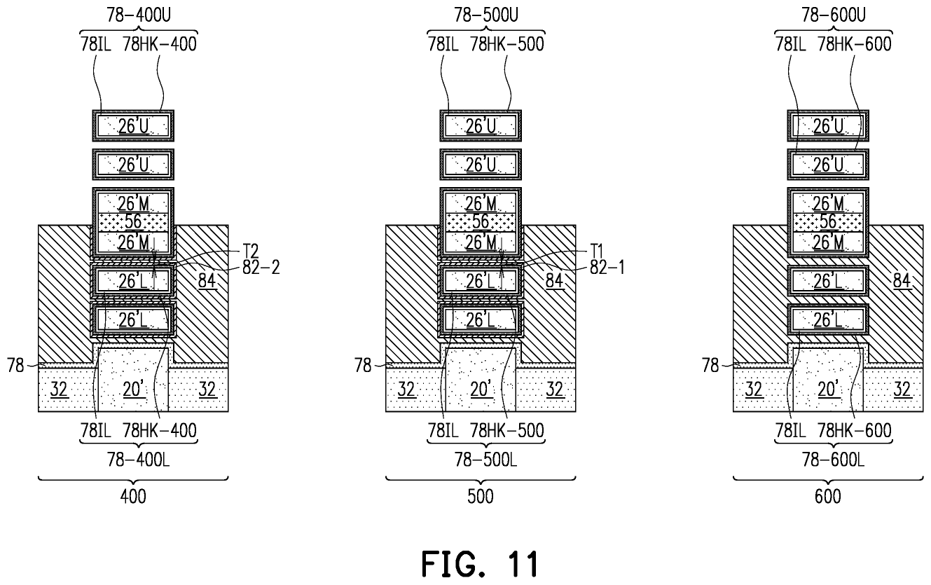

FIGS. 9-15 illustrate the details for forming gate dielectrics 78 and common gate electrodes 80 (including 80U and 80L) in accordance with some embodiments. Referring to FIG. 9, three device regions 400, 500, and 600 are illustrated. Each of the device regions is for forming a CFET including an upper FET and a lower FET. Each of the device regions 400, 500, and 600 as shown in FIG. 11 may be obtained from the region 86 as shown in FIG. 8B. In the illustrated example, the upper FETs are PFETs have threshold voltages different from each other, while the lower FETs are NFETs have threshold voltages different from each other. The PFET and NFET in each of the device regions 400, 500, and 600 are to share a common gate electrode. The common gate electrode of both of the PFET and the NFET comprises a work function layer formed of a p-type work function metal, which has a high work function higher than the mid work function of about 4.5 eV.

Referring to FIG. 9, gate dielectrics 78 are formed to encircle nanostructures 26′U, 26M, and 26′L. Each of the gate dielectrics 78 may include an interfacial layer 78IL, which may be formed of or comprises a group IV element, a group III element, and/or a group V element. Interfacial layer 78IL may include an oxide such as silicon oxide or a metal oxide, a silicate such as a metal silicate, combinations thereof, multi-layers thereof, or the like. The interfacial layer 78IL may have a thickness in the range between about 0.5 nm and about 2 nm. The interfacial layer 78IL may be formed of a thermal oxidation process and/or a deposition process.

The gate dielectrics 78 may also include high-k dielectric layers 78HK, which have a high dielectric constant (high-k) value greater than, for example, about 7.0, about 21, or higher. High-k dielectric layers 78HK may be formed of or comprise a metal oxide or a silicate of a metal selected from hafnium, zirconium, barium, titanium, lead, and combinations thereof. The formation methods of high-k dielectric layers 78HK may be selected from Molecular-Beam Deposition (MBD), ALD, PECVD, and the like. High-k dielectric layers 78HK may have a thickness in the range between about 1 nm and about 5 nm. The gate dielectrics 78 in device regions 400, 500, and 600 are formed in common processes.

For clarification, the gate dielectrics 78 are denoted as 78-400U and 78-400L, 78-500U and 78-500L, and 78-600U and 78-600L, with the postfixes being used to identify their corresponding device regions, and their corresponding position (upper “U” or lower “L”). Correspondingly, high-k dielectric layers 78HK are also identified as 78HK-400U and 78HK-400L, 78HK-500U and 78HK-500L, and 78HK-600U and 78HK-600L.

Dipole films 82-1 and 82-2 are deposited on the gate dielectrics 78 in device regions 500 and 400, respectively. The respective process is illustrated as process 234 in the process flow 200 as shown in FIG. 27. In device region 600, however, no dipole film is formed.

Dipole films 82-1 and 82-2 comprise a n-type dipole dopant, which when incorporated into the gate dielectrics of n-type FETs, may reduce the effective work functions and hence the threshold voltages and of the corresponding n-type FETs. The n-type dipole dopant, when incorporated into the gate dielectrics of p-type FETs, may reduce the effective work functions and hence increase the threshold voltages of the corresponding p-type FETs. In accordance with some embodiments, dipole films 82-1 and 82-2 may comprise a material selected from one or more of an oxide(s), a nitride(s), and/or a carbide(s) of an n-type dipole dopant(s) such as La, Sr, Y, Er, Sc, Mg, or the like, or combinations thereof.

Dipole films 82-1 and 82-2 may be formed through a plurality of conformal deposition processes (such as ALD, CVD, or the like) and a plurality of patterning processes. Dipole films 82-1 and 82-2 have thicknesses T2 and T1, respectively, with thickness T2 being greater than thickness T1. An example formation process may include depositing a first dipole film having thickness (T2−T1) on the gate dielectrics 78 in device regions 400, 500, and 600, performing a first patterning process to remove the first dipole film from device region 500, depositing a second dipole film having thickness T1 on the gate dielectrics 78 in device regions 400, 500, and 600, and performing a second patterning process to remove both of the first dipole film and the second dipole film from device region 600.

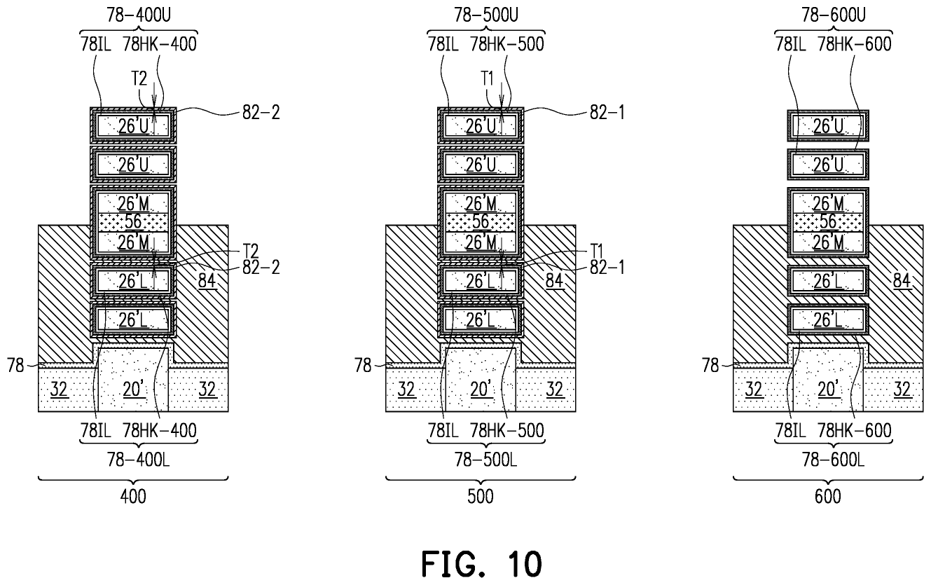

Referring to FIG. 10, dummy filling-regions 84 are formed in device regions 400, 500, and 600. The respective process is illustrated as process 236 in the process flow 200 as shown in FIG. 27. In accordance with some embodiments, dummy filling-regions 84 are formed of a material that has a high etching selectivity to the exposed features of the structure as shown in Figures 8A, 8B, and 10. For example, dummy filling-regions 84 may be formed of SiN, SiOC, SiO, SiOCN, SiCN, AlO, AlN, CON, or the like. The formation process may include depositing a filling material to fully fill recesses 74 (FIG. 8B), performing a planarization process to level the top surface of the filling material, and etching back the filling material. The etching process is controlled, so that the top surfaces of dummy filling-region 84 are at a level between the top surface level and the bottom surface level of dielectric isolation layers 56, while the top surface may be slightly higher or lower. Dummy filling-region 84 may have a planar top surface within process variation.

Next, an isotropic etching process is performed, as shown in FIG. 11. The etching process may be a wet etching process or a dry etching process, which are isotropic. The etching chemical is selected to etch dipole films 82-1 and 82-2, and stops on high-k dielectric layers 78HK. The respective process is illustrated as process 238 in the process flow 200 as shown in FIG. 27. Accordingly, the portions of dipole films 82-1 and 82-2 on upper semiconductor nanostructures 26′U and the upper one of the middle semiconductor nanostructures 26′M are removed. The portions of dipole films 82-1 and 82-2 on lower semiconductor nanostructures 26′L and the lower one of the middle semiconductor nanostructures 26′M are protected from being removed.

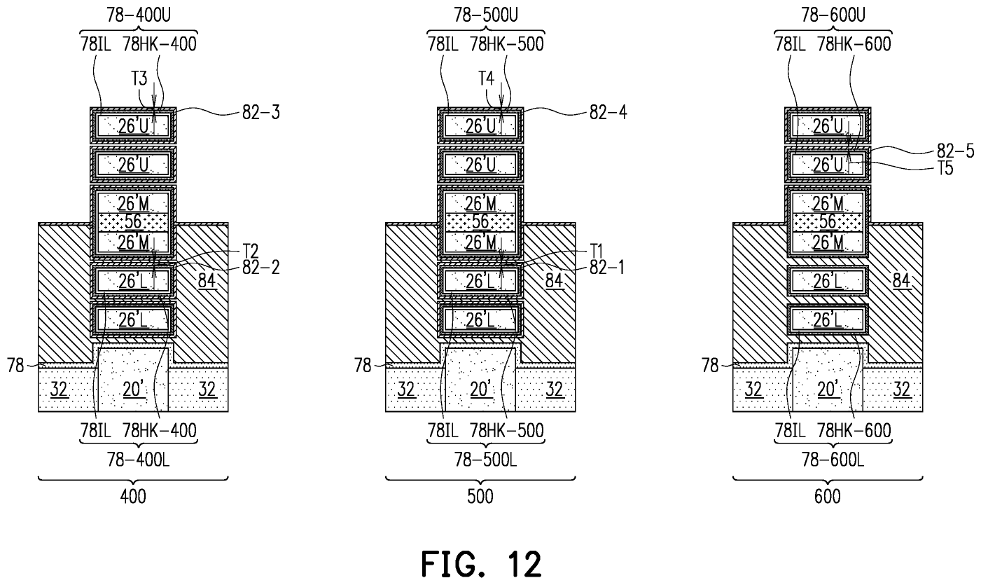

In FIG. 12, dipole films 82-3, 82-4, and 82-5 are deposited on the gate dielectrics 78 in device regions 400, 500, and 600, respectively. The respective process is illustrated as process 240 in the process flow 200 as shown in FIG. 27. Dipole films 82-1, 82-2, 82-3, 82-4, and 82-5 are individually and collectively referred to as dipole films 82 hereinafter. Dipole films 82-3, 82-4, and 82-5 have thicknesses T3, T4, and T5, respectively.

In accordance with some embodiments, there exists the relationship T5>T4>T3>T2>T1. Thicknesses T1 through T5 may range between about 0.3 nm and about 1.5 nm, and the specific range of each of thicknesses T1 through T5 is selected based on the desirable atomic percentages of the dipole dopant in the respective high-k dielectric layers 78HK. In accordance with some embodiments, thickness T1 is in the range between about 0.3 nm and about 0.4 nm, and thickness T5 is in the range between about 1.3 nm and about 1.6 nm. Thicknesses T2, T3, and T4, which are greater than thickness T1 and smaller than thickness T5, are selected based on the desirable atomic percentages of the dipole dopant in the respective high-k dielectric layers 78HK.

It is appreciated that although thicknesses T3, T4, and T5 are in device regions 400, 500, and 600, respectively, in the illustrated example, depending on circuit requirement, each of the thicknesses T3, T4, and T5 may be in any of the device regions 400, 500, and 600 in any combination.

Dipole films 82-3, 82-4, and 82-5 also comprise a n-type dipole material, which may be selected from the same group of candidate materials for forming dipole films 82-1 and 82-2. For example, dipole films 82-3, 82-4, and 82-5 may comprise the oxides, nitrides, and/or carbides of an n-type dipole dopant(s) such as La, Sr, Y, Er, Sc, Mg, or the like, or combinations thereof. The n-type dipole material of dipole films 82-3, 82-4, and 82-5 may also be the same as or different from the n-type dipole material of dipole films 82-1 and 82-2.

Dipole films 82-3, 82-4, and 82-5 may be formed through a plurality of conformal deposition processes and a plurality of patterning processes. For example, the formation process may include depositing a first dipole film into device regions 400, 500, and 600, removing the first dipole film from device regions 400 and 500, depositing a second dipole film into device regions 400, 500, and 600, removing the first dipole film and the second dipole film from device region 400, and depositing a third dipole film into device regions 400, 500, and 600. The thicknesses of the first dipole film, the second dipole film, and the third dipole film are selected to achieve desirable thicknesses T3, T4, and T5.

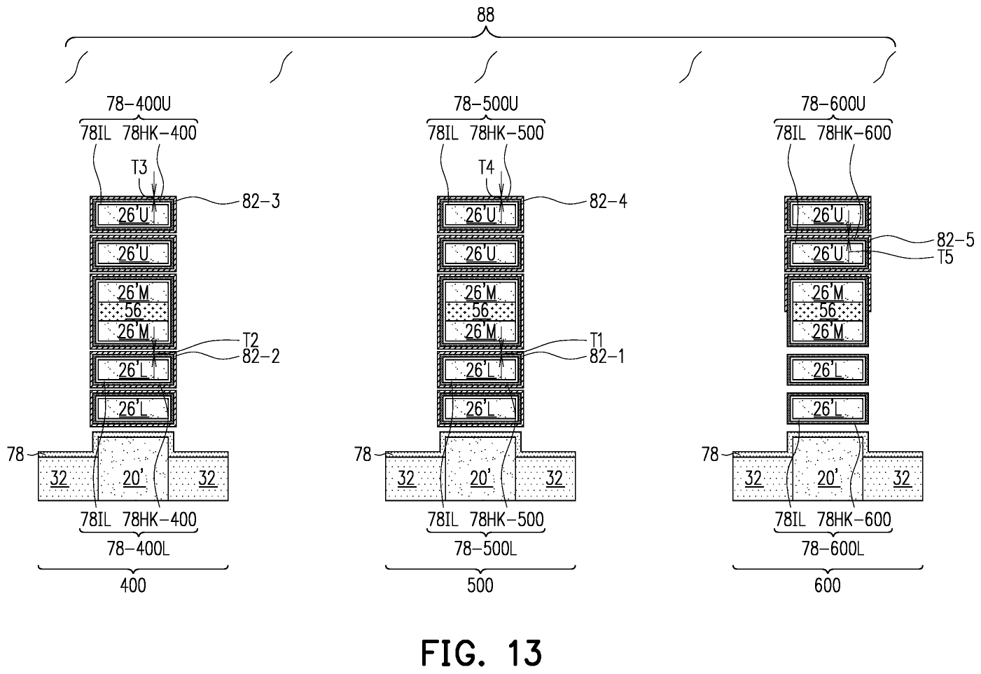

In a subsequent process, dummy filling-region 84 is removed to expose dipole films 82-1 and 82-2, and to expose the high-k gate dielectric layer 78HK-600L. The respective process is illustrated as process 242 in the process flow 200 as shown in FIG. 27. The resulting structure is shown in FIG. 13. On dummy filling-regions 84, there are some horizontal portions of the dipole film material. These portions of the dipole film material may be removed through an anisotropic etching process or a physical removal process (which is anisotropic) such as sputtering, wherein argon, for example, may be used.

After the removal of dummy fill regions 84, all dipole films 82-1, 82-2, 82-3, 82-4, and 82-5 are exposed. In device region 400, dipole films 82-3 and 82-2 have thicknesses T3 and T2, respectively. In device region 500, dipole films 82-4 and 82-1 have thicknesses T4 and T1, respectively. In device region 600, dipole films 82-5 has thicknesses T5, and no dipole film is formed on high-k gate dielectric layer 78HK-600L.

Further referring to FIG. 13, anneal process 88 is performed to drive the dipole dopants in the dipole films 82 into the respective underlying high-k dielectric layers 78HK. The respective process is illustrated as process 244 in the process flow 200 as shown in FIG. 27. The anneal process 88 may be performed in a process gas such as N₂, He, NH₃, Ar, or the like, or the mixture thereof. In accordance with some embodiments, anneal process 88 is performed through a soak anneal process, a spike rapid thermal anneal process, or the like. When the soak anneal process is adopted, the annealing duration may be in the range between about 5 seconds and about 5 minutes. The annealing temperature may be in the range between about 500° C. and about 850° C. When the spike rapid thermal anneal process is adopted, the annealing duration may be in the range between about 0.5 seconds and about 3.5 seconds. The annealing temperature may be in the range between about 700° C. and about 850° C.

The annealing results in the dipole dopant in the dipole films 82 to be driven into the respective underlying high-k dielectric layer 78HK. The atomic percentages of the dipole dopant in high-k dielectric layers 78HK-400U(T3), 78HK-400L(T2), 78HK-500U(T4), 78HK-500L(T2), and 78HK-600U(T5) are denoted as AP78-400U(T3), AP78-400L(T2), AP78-500U(T4), AP78-500L(T1), and AP78-600U(T5), respectively, wherein the thickness values (in parenthesis) following the reference notations of the high-k dielectric layers and the atomic percentage values are used to indicate the thicknesses of the respective dipole films for clarity and for easy correspondence.

It is appreciated that thicker dopant films result in the respective underlying high-k dielectric layers to have higher dopant atomic percentages of the dipole dopant, and vice versa. Accordingly, there exists the relationship AP78-600U(T5)>AP78-500U(T4)>AP78-400U(T3) >AP78-400L(T2)>AP78-500L(T1). Furthermore, since high-k dielectric layer 78HK-600L has no dipole film formed thereon, high-k dielectric layer 78HK-600L may or may not have the dipole dopant therein, depending on whether the high-k dielectric layer 78HK-600L (as deposited) comprises the dipole dopant or not. There also exists the relationship AP78-500L(T1) >AP78-600L.

Assuming dipole dopant atomic percentage AP78-500L(T2) is considered as being a base (reference) atomic percentage value APB, the dipole dopant atomic percentage AP78-400L(T2) may be in the range between about 1.5 APB and about 2.0 APB. The dipole dopant atomic percentage AP78-400U(T3) may be in the range between about 3.0 APB and about 3.5 APB. The dipole dopant atomic percentage AP78-500U(T4) may be in the range between about 7.0 APB and about 7.5 APB. The dipole dopant atomic percentage AP78-600U(T5) may be in the range between about 10.0 APB and about 10.5A PB. The dipole dopant atomic percentages and their ratios may be found through Energy Dispersive X-ray Spectroscopy (EDS), Electron Energy Loss Spectroscopy (EELS), and/or Secondary Ion Mass Spectrometry (SIMS). The desirable dipole dopant atomic percentages may be achieved by forming the dipole films 82 with proper thicknesses.

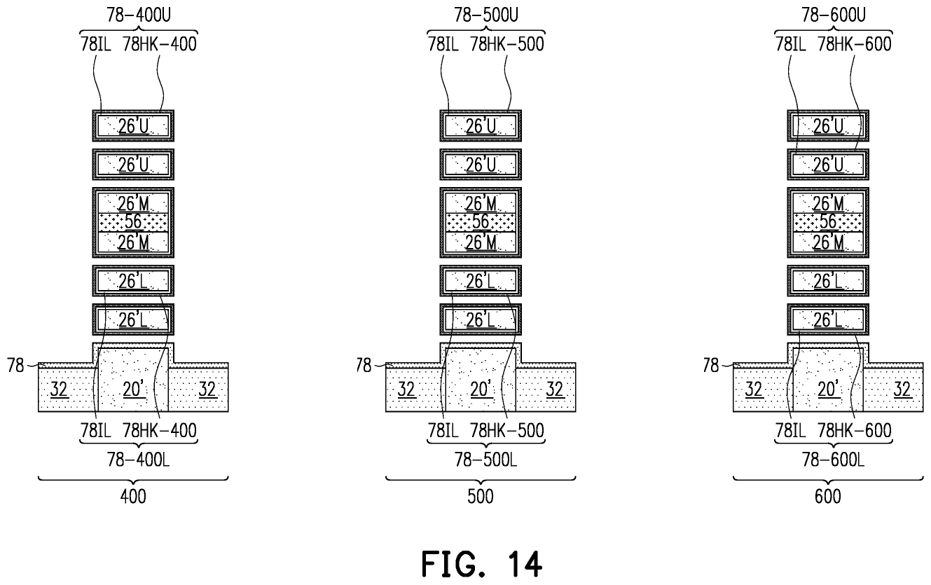

Dipole films 82 are then removed in an isotropic etching process. The resulting structure is shown in FIG. 14, wherein high-k dielectric layers 78HK are exposed.

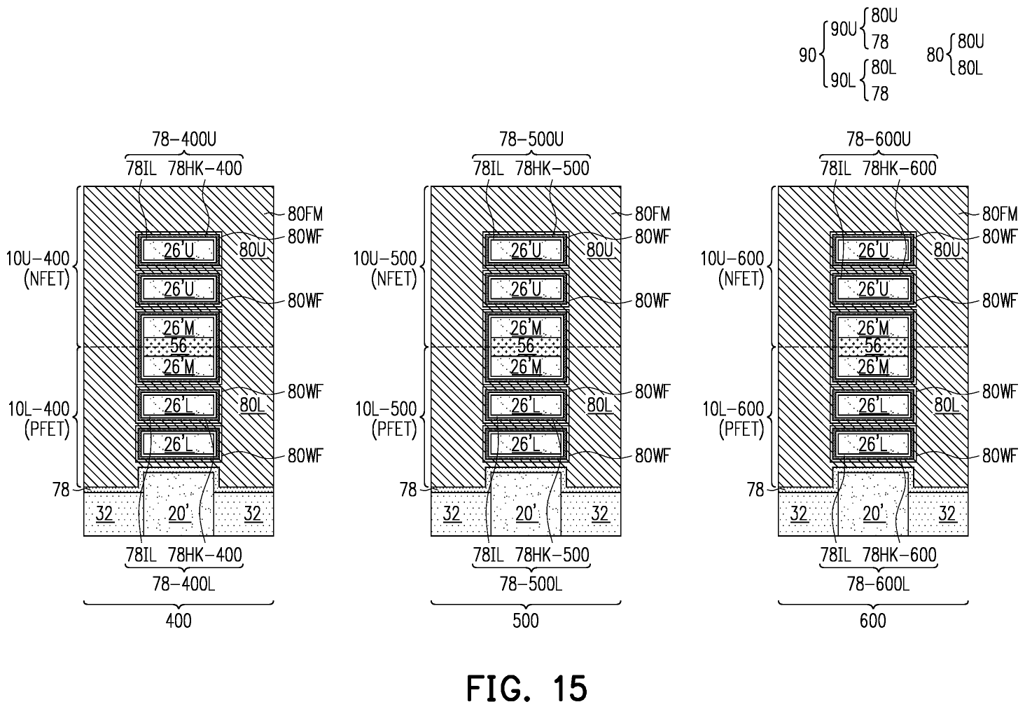

FIG. 15 illustrates the formation of gate electrodes 80. The respective process is illustrated as process 246 in the process flow 200 as shown in FIG. 27. Gate dielectrics 78 and the respective gate electrodes 80 are collectively referred to as gate stacks 90, which include upper gate stack 90U and lower gate stack 90L. The upper FET and the lower FET in each of device regions 400, 500, and 600 share a common gate electrode 80. The upper portions of the gate electrodes 80 that are higher than dielectric isolation layers 56 are referred to as upper gate electrodes 80U. The lower portions of the gate electrode that are lower than dielectric isolation layers 56 are referred to as lower gate electrodes 80L. Gate electrodes 80 may include a plurality of layers include TiN, TaN, or the like, and may include one or more work function layers 80WF. The thickness of each of the layers in gate electrodes 80 may be in the range between about 2 nm and about 5 nm.

The work function layers 80WF encircling each of the gate dielectrics 78 may be physically separate from the work function layers 80WF encircling other ones of the gate dielectrics 78. In which case, a (non-work-function) filling metal region 80FM (such as tungsten, cobalt, ruthenium, or the like) may fill the spaces between the work function layers 80WF on neighboring gate dielectrics 78. Alternatively, the work function layers 80WF encircling each of the gate dielectrics 78 may be physically joined to the work function layers 80WF encircling other ones of the gate dielectrics 78.

In accordance with some embodiments, the work function layers 80WF have a p-type work function, which is higher than about 4.8 eV, and may be in the range between about 4.8 eV and about 5.2 eV.

The resulting FETs includes upper FET 10U-400 and lower FET 10L-400 in device region 400, upper FET 10U-500 and lower FET 10L-500 in device region 500, and upper FET 10U-600 and lower FET 10L-600 in device region 600. The upper FETs 10U-400, 10U-500, and 10U-600 are NFETs, and the lower FETs 10L-400, 10L-500, and 10L-600 are PFETs.

As aforementioned, the gate electrodes 80 of the n-type upper FETs 10U-400, 10U-500, and 10U-600 have p-type work function layers with high work function values, for example, higher than about 4.8 eV. The n-type FETs, however, prefer n-type work functions, which have low work function values, for example, smaller than about 4.5 eV, such as between about 4.0 eV and about 4.5 eV. In accordance with the embodiments of the present disclosure, this conflict is solved by heavily doping the high-k dielectric layers 78HK of the NFETs with the n-type dipole dopant, so that the effective work functions of the p-type work function layers 80WF in the NFETs are reduced to the n-type work function range, for example, between about 4.0 eV and about 4.5 eV.

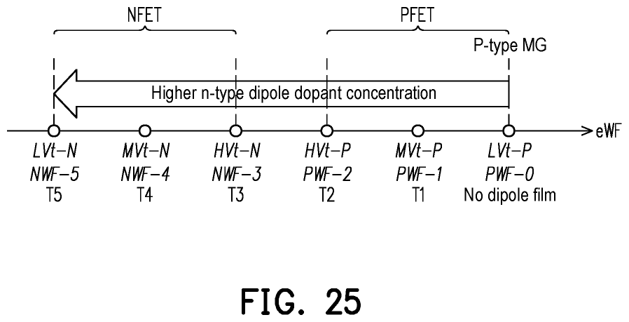

FIG. 25 illustrates the effect of doping n-type dipole dopants to reduce effective work functions, and the effect of the doping on the threshold voltages of the respective FETs. In the direction of an arrow marked as “eWF” (representing effective work function), the thicknesses of the dopant film reduce, and the effective work functions increase increasingly, although the same work function material is used. It is appreciated that with the increase in the thicknesses of the n-type dopant films, the respective effect work function layer is reduced from a high p-type work function PWF-0 to a mid p-type work function PWF-1, and then to a low p-type work function PWF-2. Further increasing the thicknesses of the n-type dopant films, the respective effect work function layer is reduced to a high n-type work function NWF-3, to a mid n-type work function NWF-4, and then to a low n-type work function NWF-5.

As also shown in FIG. 25, the PFETs have threshold voltages LVt-P, MVt-P, and LVT-P, which correspond to having no dipole film, having the dipole film with the thickness T1, and having the dipole film with the thickness T2, respectively. The NFETs have threshold voltages HVt-N, MVt-N, and LVT-N, which correspond the dipole films having thicknesses T3, T4, and T5, respectively. Accordingly, when the gate electrodes of multiple NFETs and PFETs are formed of the same p-type work function material(s), the effective work functions may be adjusted to proper values by adjusting the thicknesses of the dipole films, and both of the n-type effective work functions and the effective p-type work functions may be achieved, leading to desirable threshold voltages.

Referring again to FIG. 15, NFETs 10U-400, 10U-500, and 10U-600 have high threshold voltage HVt-N, middle threshold voltage MVt-N, and low threshold voltage LVt-N, respectively. PFETs 10L-400, 10L-500, and 10L-600 have high threshold voltage HVt-P, middle threshold voltage MVt-P, and low threshold voltage LVt-P, respectively.

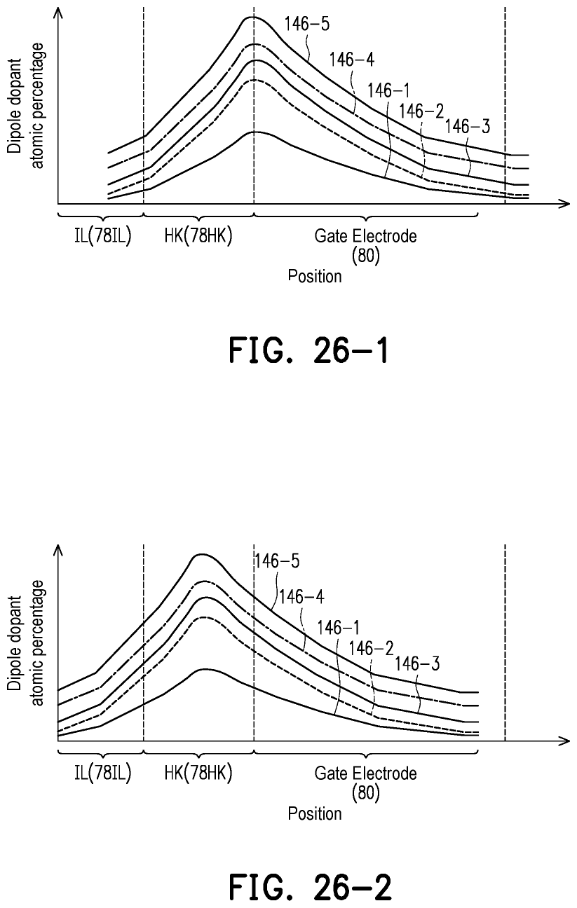

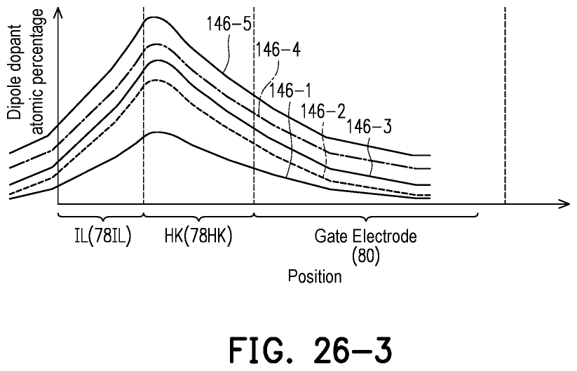

It is appreciated that the dipole dopants are diffused from dipole films, which are removed after the diffusion. Accordingly, after the removal of the dipole films 82, the peak dipole dopant atomic percentage may occur at the outer surface of the high-k dielectric layers 78HK, which will be in contact with the later-formed gate electrodes 80. FIG. 26-1 schematically illustrates the dipole dopant atomic percentages as a function of positions, where the dipole dopant distribution in interfacial layer 78IL, high-k dielectric layer 78HK, and gate electrode 80 are illustrated. Lines 146-1, 146-2, 146-3, 146-4, and 146-5 correspond to the dipole film thicknesses T1, T2, T3, T4, and T5, respectively. The peak dipole dopant atomic percentages may occur at the interface between high-k dielectric layers 78HK and the corresponding gate electrodes 80. Alternatively, the peak dipole dopant atomic percentages may be inside high-k dielectric layers 78HK (FIG. 26-2), or at or close to the interface between high-k dielectric layers 78HK and the corresponding interfacial layers 78IL (FIG. 26-3). The peak position may slightly shift left or right, for example, with shifting distances smaller than about 1 nm.

By adopting the same materials for forming the gate electrodes of both of the PFETs and NFETs, there is no need to etch the gate electrodes from the upper FETs, and then form the gate electrodes again for the upper FETs. The etching of the gate electrodes may damage the high-k dielectric layers. Accordingly, in accordance with the embodiments of the present disclosure, the damage to the high-k dielectric layers is avoided due to the use of common gate electrodes.

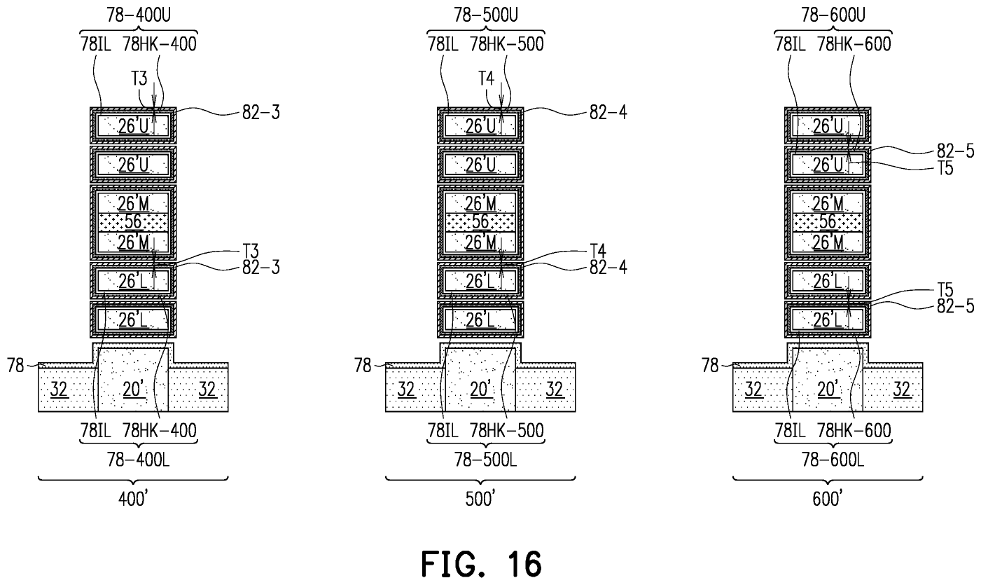

FIGS. 16 through 22 illustrate the formation of CFETs in accordance with alternative embodiments. These embodiments are similar to the embodiments in FIGS. 9 through 15, except that upper FETs are PFETs, while lower FETs are NFETs. The gate electrodes of both of PFETs and the NFETs are also formed of a same work function material with a high p-type work function, and the effective work functions of the gate electrodes are adjusted by doping an n-type dipole dopant to desirable values. Unless specified otherwise, the materials, the structures, the thicknesses, and the formation processes in accordance with these embodiments may be essentially the same as what are discussed referring to FIGS. 9 through 15, and may not be repeated herein.

Referring to FIG. 16, a plurality of gate dielectrics 78 are formed in device regions 400′, 500′, and 600′, respectively. Dipole films 82-3, 82-4, and 82-5 are formed, which have thicknesses T3, T4, and T4, respectively, as discussed referring to the preceding embodiments.

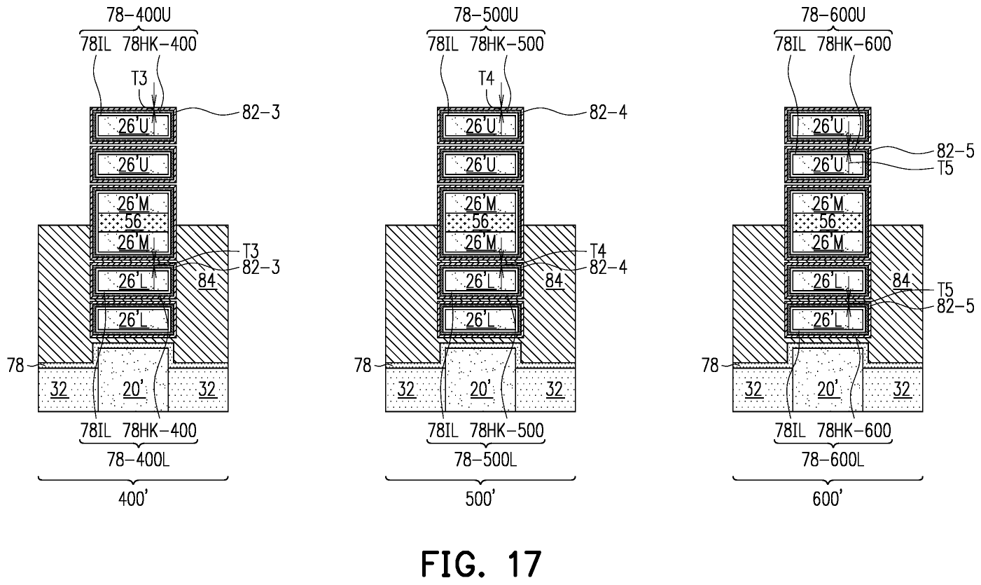

Referring to FIG. 17, dummy filling-regions 84 are formed, and are etched back to mask the dipole films 82-3, 82-4, and 82-5 in lower FET regions, while leaving the portions of dipole films 82-3, 82-4, and 82-5 in upper FET regions exposed.

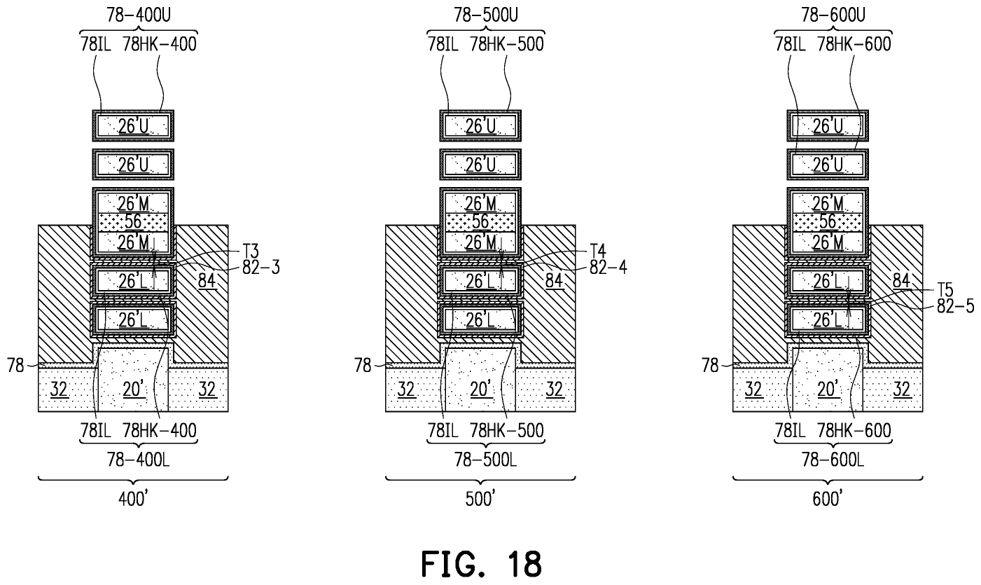

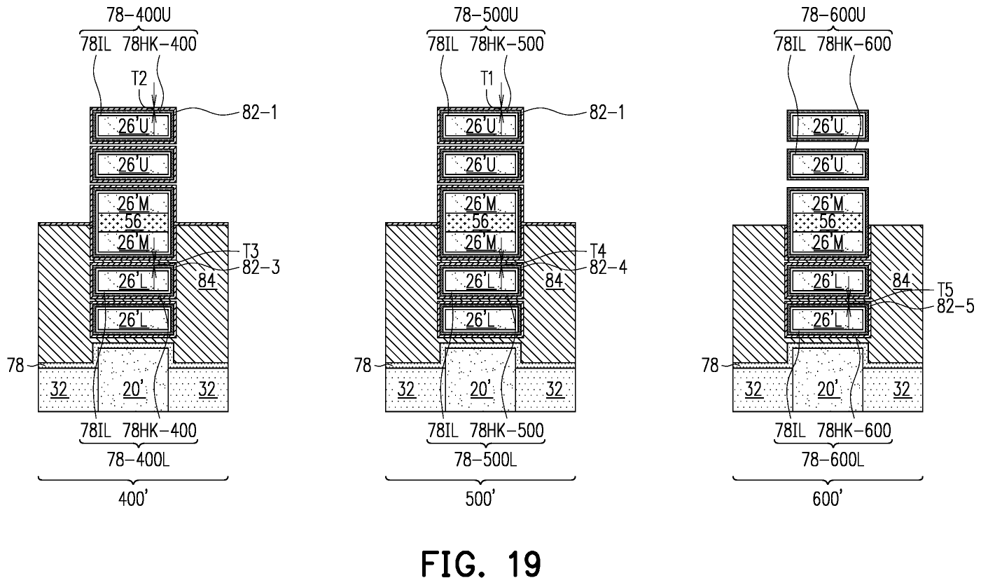

FIG. 18 illustrates the removal of dipole films 82-3, 82-4, and 82-5 from the upper FET regions. The high-k dielectrics 78HK (including 78HK-400, 78HK-500, and 78HK-600) in the upper FET regions are thus exposed. Next, as shown in FIG. 19, dipole films 82-2 and 82-1 are formed on the gate dielectrics 78 in the upper FET regions in device regions 400 and 500, respectively. No dipole film is formed in device region 600. Dipole films 82-2 and 82-1 have thicknesses T2 and T1, respectively, as discussed referring to the preceding embodiments.

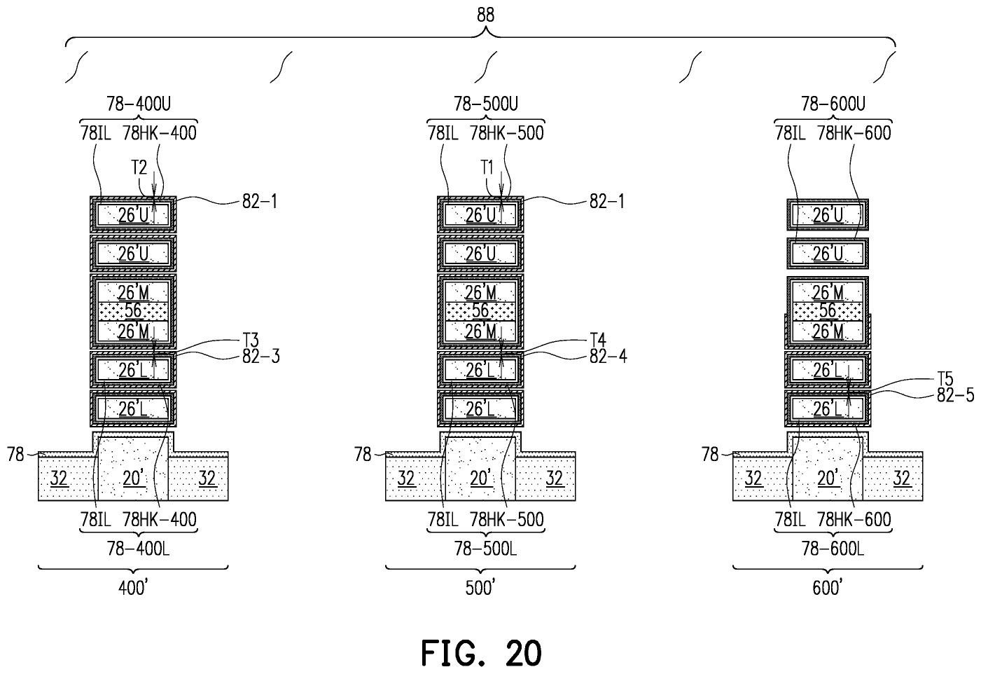

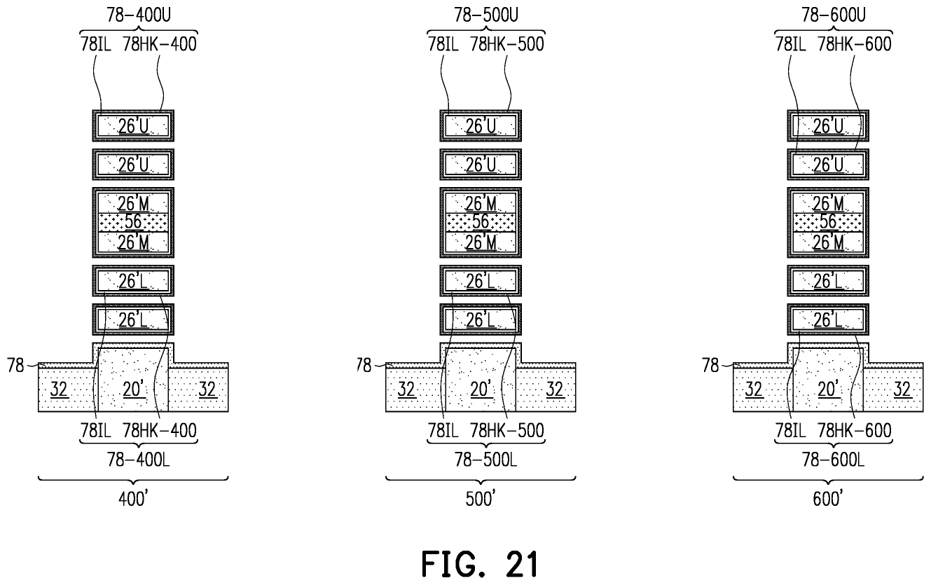

FIG. 20 illustrates the removal of dummy filling-regions 84, followed by anneal process 88 to drive the dipole dopants in dipole films 82 into the respective underlying high-k dielectrics 78HK. Next, the dipole films 82 are removed in an etching process, exposing the underlying high-k dielectric layers 78HK. The resulting structure is shown in FIG. 21.

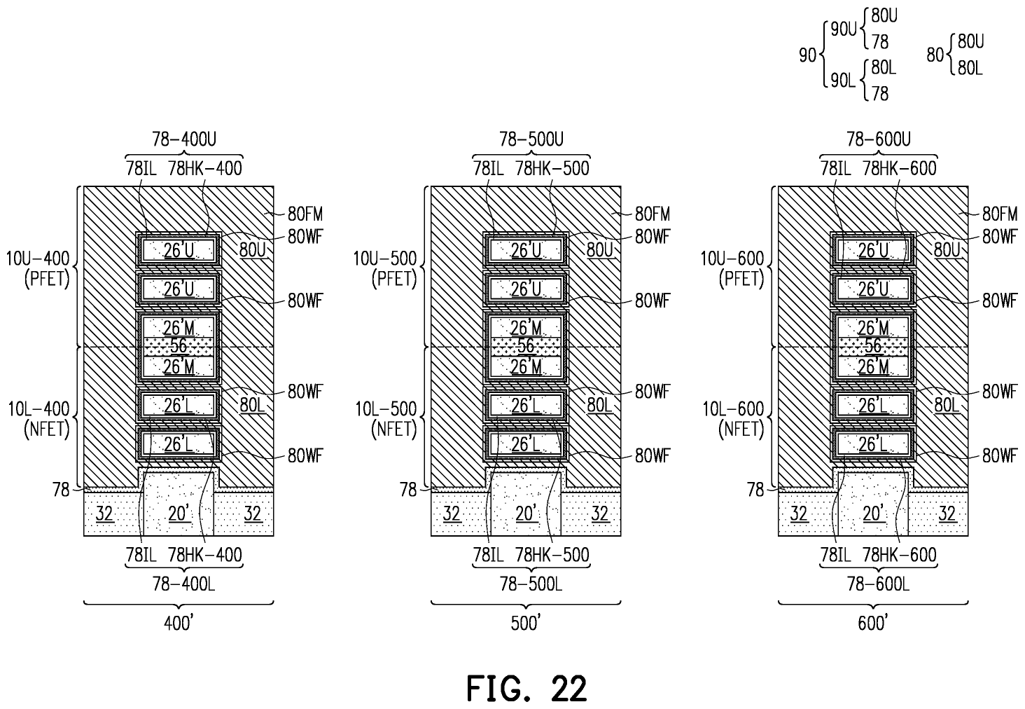

FIG. 22 illustrates the formation of gate electrodes 80 for CFETs. The resulting upper FETs 10U-400, 10U-500, and 10U-600 are PFETs, and the lower FETs 10L-400, 10L-500, and 10L-600 are NFETs. The dipole dopant atomic percentages in high-k dielectric layers 78HK-600U, 78HK-500U(T1), 78HK-400U(T2), 78HK-400L(T3), 78HK-500L(T4), and 78HK-600L(T5) are increasingly higher due to increasingly thicker dipole films. The effective work function values of the gate electrodes of 10U-600, 10U-500, and 10U-400, 10L-400, 10L-500, and 10L-600, are increasingly lower. The threshold voltages of upper FETs 10U-400, 10U-500, and 10U-600 are HVt-P, MVt-P, and LVt-P, respectively, which are increasingly lower. The threshold voltages of lower FETs 10L-400, 10L-500, and 10L-600 are HVt-N, MVt-N, and LVt-N, respectively, which are also increasingly lower. Again, the combination of the thicknesses of dipole dopant films in the upper FETs and the thicknesses of dipole dopant films in the lower FETs is an example, and any combination may be used.

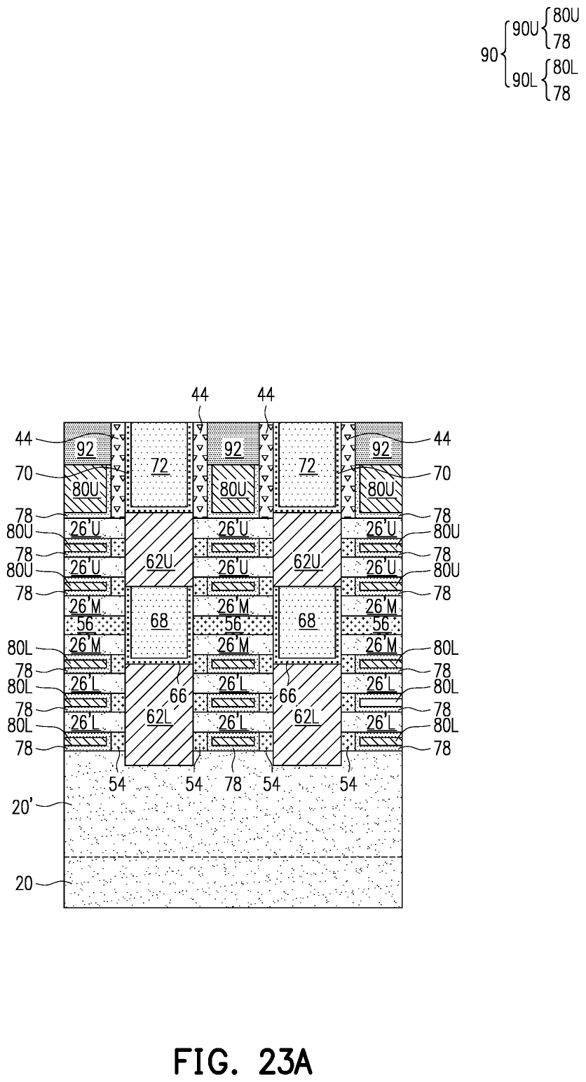

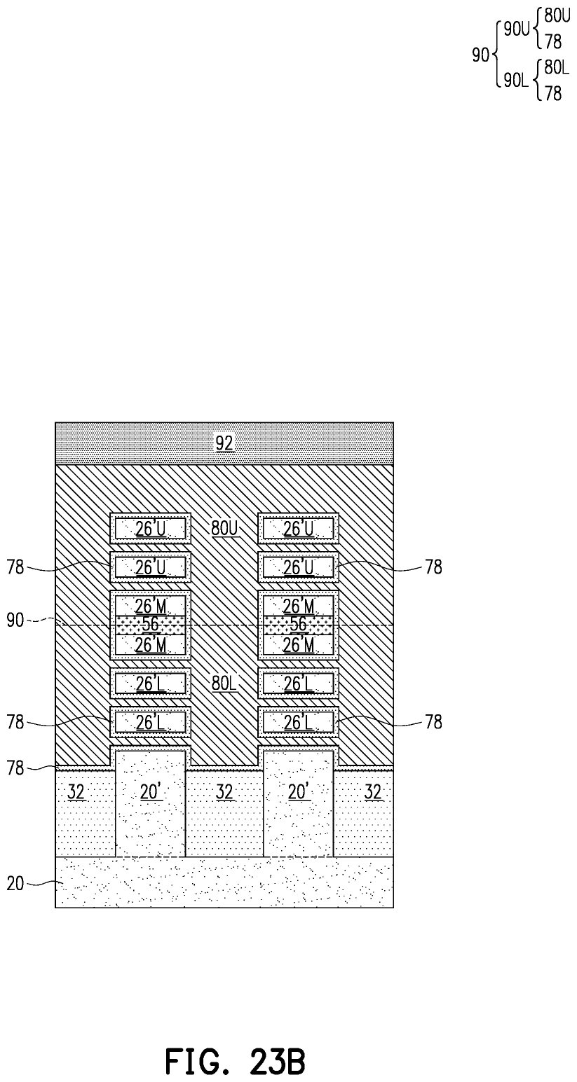

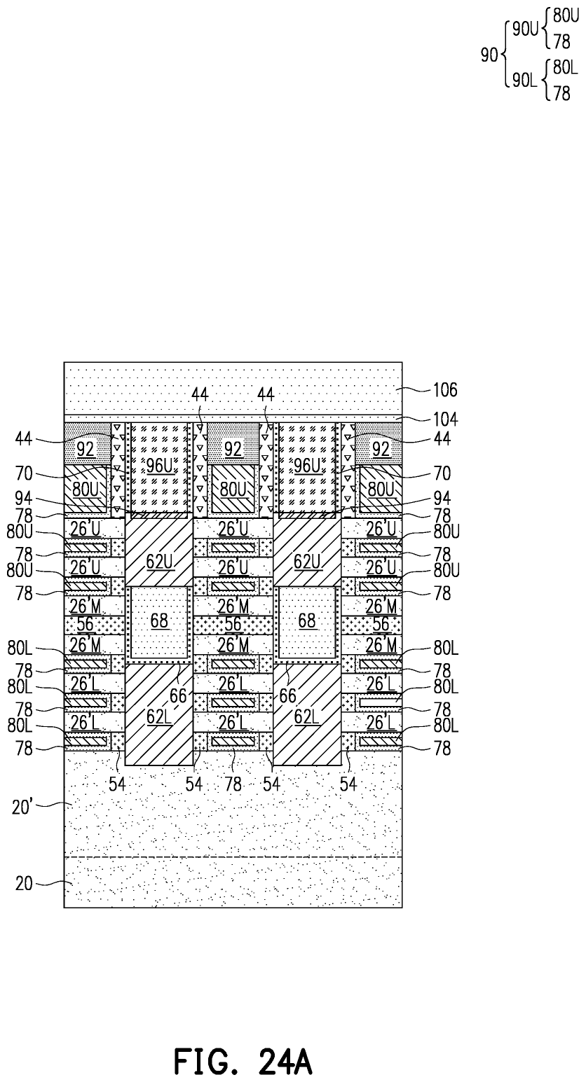

FIGS. 23A and 23B illustrate the cross-sectional views of an example CFET formed in preceding processes. Each of the CFETs in device regions 400, 500, and 600 may be represented by the CFETs shown in FIGS. 23A and 23B. The common gate electrode 80 includes upper electrode 80U and lower electrode 80L, which are formed in the same processes and same materials.

As also shown in FIGS. 23A and 23B, gate masks 92 are formed over the dummy gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72. Silicide regions 94 and source/drain contact plugs 96U are formed to electrically couple to the source/drain regions 62U.

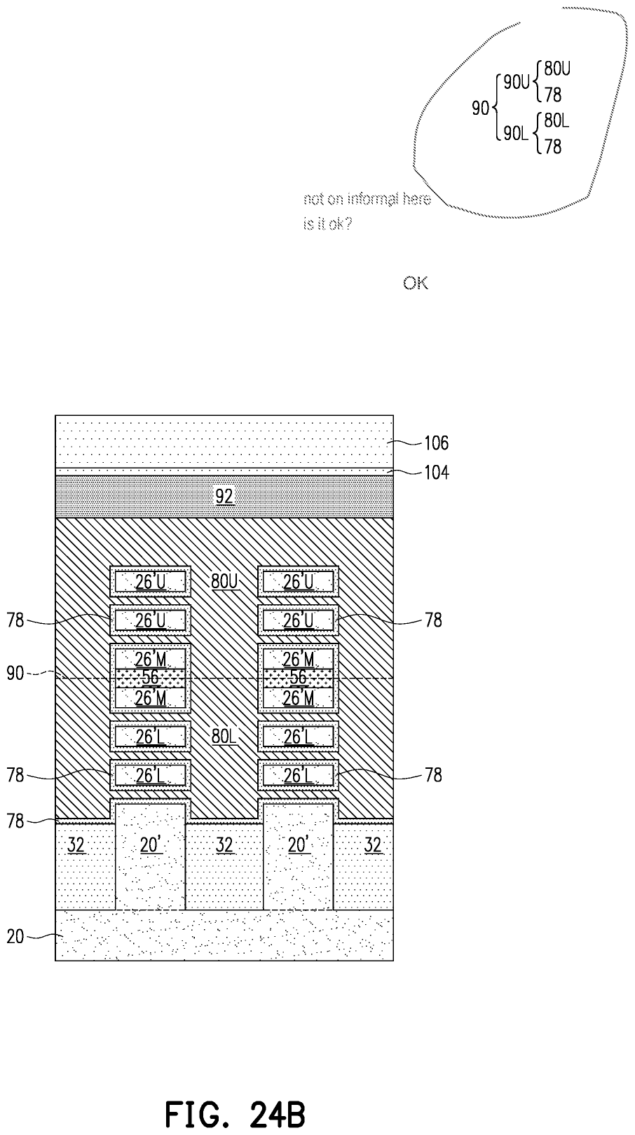

Referring to FIGS. 24A and 24B, an etch stop layer (ESL) 104 and a third ILD 106 are formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

The embodiments of the present disclosure have some advantageous features. A same work function material such as a p-type work function material is used to form the gate electrodes of multiple PFET and multiple PFETs. By doping dipole dopants (such as an n-type dipole dopant) into gate dielectrics of the multiple FETs to different atomic percentage, the effective work functions of the multiple FETs may be adjusted to different levels, and different threshold voltages may be achieved.

In accordance with some embodiments, a method comprises forming a first semiconductor channel region and a second semiconductor channel region, wherein the second semiconductor channel region overlaps the first semiconductor channel region; forming a first gate dielectric on the first semiconductor channel region; forming a second gate dielectric on the second semiconductor channel region; forming a first dipole film and a second dipole film on the first gate dielectric and the second gate dielectric, respectively; driving in dipole dopants in the first dipole film and the second dipole film into the first gate dielectric and the second gate dielectric, respectively; removing the first dipole film and the second dipole film; and forming a gate electrode on both of the first gate dielectric and the second gate dielectric, wherein the gate electrode and the first gate dielectric are comprised in a first transistor, and the gate electrode and the second gate dielectric are comprised in a second transistor.

In an embodiment, work function layers in the gate electrode have p-type work functions, and wherein a first one of the first transistor and the second transistor is a p-type transistor, and a second one of the first transistor and the second transistor is an n-type transistor. In an embodiment, the first transistor is the p-type transistor, and the second transistor is the n-type transistor, and wherein the second dipole film is thicker than the first dipole film. In an embodiment, the first transistor is the n-type transistor, and the second transistor is the p-type transistor, and wherein the second dipole film is thinner than the first dipole film. In an embodiment, the method further comprises forming a first source/drain region aside the first semiconductor channel region; and forming a second source/drain region aside the second semiconductor channel region, wherein the second source/drain region overlaps the first source/drain region.

In an embodiment, the method further comprises forming a first contact plug overlying and electrically coupling to the first source/drain region; and forming a second contact plug underlying and electrically coupling to the second source/drain region. In an embodiment, the first transistor and the second transistor are of opposite conductivity types. In an embodiment, the method further comprises forming a plurality of transistors at a same level as the first transistor, wherein the forming the plurality of transistors comprises adopting a plurality of dipole films comprising a same dipole as the first dipole film, wherein the plurality of dipole films have thicknesses different from each other, and wherein gate electrodes of the plurality of transistors are formed in common processes and have same materials.

In an embodiment, the forming the first dipole film and the second dipole film comprises depositing the first dipole film on both of the first gate dielectric and the second gate dielectric; removing the first dipole film from the second gate dielectric; and forming the second dipole film on the second gate dielectric. In an embodiment, the method further comprises, after the first dipole film is deposited, forming a sacrificial layer to contact both of the first gate dielectric and the second gate dielectric; recessing the sacrificial layer to a level lower than the second gate dielectric, wherein the first dipole film is removed from the second gate dielectric after the recessing, and the second dipole film is deposited after the first dipole film is removed from the second gate dielectric; and removing the sacrificial layer.

In accordance with some embodiments, structure comprises a lower transistor comprising a first channel region; a first gate dielectric on the first channel region; and a first gate electrode on the first gate dielectric; and an upper transistor, wherein a first transistor in the lower transistor and the upper transistor is an n-type transistor, and wherein a second transistor in the lower transistor and the upper transistor is a p-type transistor, and wherein the upper transistor comprises a second channel region overlapping the first channel region; a second gate dielectric on the second channel region; and a second gate electrode on the second gate dielectric, wherein the first gate electrode and the second gate electrode are parts of a same gate electrode.

In an embodiment, both of the first gate electrode and the second gate electrode comprise a work function layer having a p-type work function. In an embodiment, the p-type transistor has a p-type effective work function, and the n-type transistor has an n-type effective work function. In an embodiment, the first gate dielectric and the second gate dielectric comprise a same dipole dopant, and wherein a first dipole dopant atomic percentage in the n-type transistor is higher than a second dipole dopant atomic percentage in the p-type transistor.

In an embodiment, the same dipole dopant is selected from the group consisting of La, Sr, Y, Er, Sc, Mg, and combinations thereof. In an embodiment, a ratio of the first dipole dopant atomic percentage to the second dipole dopant atomic percentage is higher than about 3.0. In an embodiment, the upper transistor is the n-type transistor, and the lower transistor is the p-type transistor.

In accordance with some embodiments, structure comprises a lower transistor comprising a first channel region; a first gate dielectric on the first channel region; and a first source/drain region connecting to the first channel region; and an upper transistor comprising a second channel region overlapping the first channel region; a second gate dielectric on the second channel region; and a second source/drain region connecting to the second channel region, wherein the second source/drain region overlaps the first source/drain region, and wherein the first source/drain region and the second source/drain region have opposite conductivity types; and a common gate electrode continuously extending from a first level lower than the first channel region to a second level higher than the second channel region.

In an embodiment, the common gate electrode comprises a lower portion acting as a first gate electrode of the lower transistor; and an upper portion acting as a second gate electrode of the upper transistor, wherein no interface is formed between the lower portion and the upper portion. In an embodiment, the common gate electrode comprises p-type work function layers encircling each of the first gate dielectric and the second gate dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor channel region and a second semiconductor channel region, wherein the second semiconductor channel region overlaps the first semiconductor channel region;
forming a first gate dielectric on the first semiconductor channel region;
forming a second gate dielectric on the second semiconductor channel region;
forming a first dipole film and a second dipole film on the first gate dielectric and the second gate dielectric, respectively;
driving in dipole dopants in the first dipole film and the second dipole film into the first gate dielectric and the second gate dielectric, respectively;
removing the first dipole film and the second dipole film; and
forming a gate electrode on both of the first gate dielectric and the second gate dielectric, wherein the gate electrode and the first gate dielectric are comprised in a first transistor, and the gate electrode and the second gate dielectric are comprised in a second transistor.

2. The method of claim 1, wherein work function layers in the gate electrode have p-type work functions, and wherein a first one of the first transistor and the second transistor is a p-type transistor, and a second one of the first transistor and the second transistor is an n-type transistor.

3. The method of claim 2, wherein the first transistor is the p-type transistor, and the second transistor is the n-type transistor, and wherein the second dipole film is thicker than the first dipole film.

4. The method of claim 2, wherein the first transistor is the n-type transistor, and the second transistor is the p-type transistor, and wherein the second dipole film is thinner than the first dipole film.

5. The method of claim 1 further comprising:
forming a first source/drain region aside the first semiconductor channel region; and
forming a second source/drain region aside the second semiconductor channel region, wherein the second source/drain region overlaps the first source/drain region.

6. The method of claim 5 further comprising:
forming a first contact plug overlying and electrically coupling to the first source/drain region; and
forming a second contact plug underlying and electrically coupling to the second source/drain region.

7. The method of claim 5, wherein the first transistor and the second transistor are of opposite conductivity types.

8. The method of claim 1 further comprising forming a plurality of transistors at a same level as the first transistor, wherein the forming the plurality of transistors comprises:
adopting a plurality of dipole films comprising a same dipole as the first dipole film, wherein the plurality of dipole films have thicknesses different from each other, and wherein gate electrodes of the plurality of transistors are formed in common processes and have same materials.

9. The method of claim 1, wherein the forming the first dipole film and the second dipole film comprises:
depositing the first dipole film on both of the first gate dielectric and the second gate dielectric;
removing the first dipole film from the second gate dielectric; and
forming the second dipole film on the second gate dielectric.

10. The method of claim 9 further comprising:
after the first dipole film is deposited, forming a sacrificial layer to contact both of the first gate dielectric and the second gate dielectric;
recessing the sacrificial layer to a level lower than the second gate dielectric, wherein the first dipole film is removed from the second gate dielectric after the recessing, and the second dipole film is deposited after the first dipole film is removed from the second gate dielectric; and
removing the sacrificial layer.

11. A structure comprising:
a lower transistor comprising:
a first channel region;
a first gate dielectric on the first channel region; and
a first gate electrode on the first gate dielectric; and
an upper transistor, wherein a first transistor in the lower transistor and the upper transistor is an n-type transistor, and wherein a second transistor in the lower transistor and the upper transistor is a p-type transistor, and wherein the upper transistor comprises:
a second channel region overlapping the first channel region;
a second gate dielectric on the second channel region; and
a second gate electrode on the second gate dielectric, wherein the first gate electrode and the second gate electrode are parts of a same gate electrode.

12. The structure of claim 11, wherein both of the first gate electrode and the second gate electrode comprise a work function layer having a p-type work function.

13. The structure of claim 11, wherein the p-type transistor has a p-type effective work function, and the n-type transistor has an n-type effective work function.

14. The structure of claim 11, wherein the first gate dielectric and the second gate dielectric comprise a same dipole dopant, and wherein a first dipole dopant atomic percentage in the n-type transistor is higher than a second dipole dopant atomic percentage in the p-type transistor.

15. The structure of claim 14, wherein the same dipole dopant is selected from the group consisting of La, Sr, Y, Er, Sc, Mg, and combinations thereof.

16. The structure of claim 14, wherein a ratio of the first dipole dopant atomic percentage to the second dipole dopant atomic percentage is higher than about 3.0.

17. The structure of claim 11, wherein the upper transistor is the n-type transistor, and the lower transistor is the p-type transistor.

18. A structure comprising:
a lower transistor comprising:
a first channel region;
a first gate dielectric on the first channel region; and
a first source/drain region connecting to the first channel region; and
an upper transistor comprising:
a second channel region overlapping the first channel region;
a second gate dielectric on the second channel region; and
a second source/drain region connecting to the second channel region, wherein the second source/drain region overlaps the first source/drain region, and wherein the first source/drain region and the second source/drain region have opposite conductivity types; and
a common gate electrode continuously extending from a first level lower than the first channel region to a second level higher than the second channel region.

19. The structure of claim 18, wherein the common gate electrode comprises:
a lower portion acting as a first gate electrode of the lower transistor; and
an upper portion acting as a second gate electrode of the upper transistor, wherein no interface is formed between the lower portion and the upper portion.

20. The structure of claim 18, wherein the common gate electrode comprises p-type work function layers encircling each of the first gate dielectric and the second gate dielectric.
